(19) United States
(12) Patent Application Publication
(10) Pub. No.: US 2025/0371221 A1
(43) Pub. Date: Dec. 4, 2025

(54) GENERATING DIGITIAL SIMULATION SCENARIOS USING SAMPLING

(71) Applicant: INTERNATIONAL BUSINESS MACHINES CORPORATION, ARMONK, NY (US)

(72) Inventors: Dilermando Queiroz Neto, São Paulo (BR); Maysa Malfiza Garcia de Macedo, São Paulo (BR); Jorge Luis Guevara Diaz, São Paulo (BR); Daniela de Mattos Szwarcman, Rio de Janeiro (BR); Bianca Zadrozny, RIO DE JANEIRO (BR); Leonardo Pondian Tizzei, Campinas (BR); Maria Julia De Castro Villafranca Garcia, São Paulo (BR)

(21) Appl. No.: 18/732,937

(22) Filed: Jun. 4, 2024

(51) Int. Cl. G06F 30/27

(52) U.S. Cl. CPC G06F 30/27

(57) ABSTRACT

Improved performance of a computer simulation using sampling can include using a computer to process a resolution reduction of input data by an upscaling technique providing upscaling of the input data. The input data including a size and a resolution, a location, a date, conditioning points, and weather variable data. The upscaling of the input data generating reduced resolution data with less resolution and less data size than the input data. A multiple-point geostatistics technique is applied to the reduced resolution data for generating a simulation of a new weather scenario, without changes in size or resolution to the reduced resolution data. The computer is used to process a resolution increase of the reduced resolution data from the simulation using a downscaling technique to return the reduced resolution data to the size and the resolution of the input data.

### BACKGROUND

The present disclosure relates to a system and method to generate computerized weather scenarios using a sampling technique.

Computing systems and computer implemented methods can be used to generate weather scenarios using sampling data. However, even with availability of hardware capable of large computations, it can be infeasible to reduce the computational cost for large data. One problem that can occur when simulating weather scenarios over a large region is the simulation can produce data with very large matrices, for example, above 250×250 data points.

### SUMMARY

The present disclosure recognizes the shortcomings and problems associated with current techniques for generating computer generated weather simulations that cover large regions that produce data with large matrices.

The present invention mitigates the problem of generating computer simulation scenarios that cover large regions that produce data with very large matrices, above 250×250 points. The invention solves the problem of high computational cost for running a multiple-point geostatistics method for weather generation scenarios without focusing on approaches that involve hardware availability. The present invention uses a system or method to generate computerized weather scenarios using an optimal multiple-point geostatistics method.

In an aspect according to the present invention, a method for improving performance of a computer simulation using sampling includes processing, using a computer, a resolution reduction of input data by an upscaling technique providing upscaling of the input data, the input data including a size and a resolution, a location, a date, conditioning points, and weather variable data. The upscaling of the input data generating reduced resolution data having a reduced resolution and a reduced data size which is less resolution and less data size than the input data. The method includes applying a multiple-point geostatistics technique to the reduced resolution data for generating, using the computer, a simulation of a new weather scenario, without changes in the reduced data size or the reduced resolution to the reduced resolution data. The method includes processing, using the computer, a resolution increase of the reduced resolution data from the simulation using a downscaling technique to return the reduced resolution data to the size and the resolution of the input data.

In a related aspect, the simulation is a digital weather simulation based on the reduced resolution data.

In a related aspect, the input data includes information related to weather including location information including latitude and longitude, conditioning points, and weather information including weather conditions and a date.

In a related aspect, the weather variables and conditions are received from a computer of a user and related to a specific location.

In a related aspect, the generated simulation is the same size as the size of the input data when received at the computer.

In a related aspect, the multipoint geostatistics technique is a direct sampling method, or a parallel direct sampling method.

In a related aspect, the upscaling is performed using a method which represents one point based on a set of points.

In a related aspect, the downscaling is performed using a method which represents a set of points based on a neighborhood or based on a previous set of data related to the location.

In a related aspect, the method further includes: when there is a database and a neural network which is pre-trained available for requested data, using the neural network to perform the upscaling or the downscaling; and when the neural network is not available, the upscaling being performed using bicubic resampling or average pooling, and the downscaling being performed using a method based on interpolation that uses one data sample.

In a related aspect, the method further including: performing upsampling and downsampling using one or more methods excluding a generative neural network when the neural network is unavailable; and performing upsampling and downsampling using the generative neural network, when the neural network is available with training data.

In another aspect according to the present invention, a system to improve performance of a computer simulation using sampling includes a computer system. The computer system comprises; a computer processor, a computer-readable storage medium, and program instructions stored on the computer-readable storage medium being executable by the processor, to cause the computer system to perform the following functions. Process, using a computer, a resolution reduction of input data by an upscaling technique providing upscaling of the input data, the input data including a size and a resolution, a location, a date, conditioning points, and weather variable data. The upscaling of the input data generating reduced resolution data having a reduced resolution and a reduced data size which is less resolution and less data size than the input data. Apply a multiple-point geostatistics technique to the reduced resolution data to generate, using the computer, a simulation of a new weather scenario, without changes in the reduced data size or the reduced resolution to the reduced resolution data. Process, using the computer, a resolution increase of the reduced resolution data from the simulation using a downscaling technique to return the reduced resolution data to the size and the resolution of the input data.

In a related aspect, the simulation is a digital weather simulation based on the reduced resolution data.

In a related aspect, the input data is information related to weather including location information including latitude and longitude, conditioning points, and weather information including weather conditions and a date.

In a related aspect, the weather variables and the conditions are received from a computer of a user and related to a specific location.

In a related aspect, the generated simulation is the same size as the size of the input data when received at the computer.

In a related aspect, the multipoint geostatistics technique is a direct sampling method, or a parallel direct sampling method.

In a related aspect, the upscaling is performed using a method which represents one point based on a set of points.

In a related aspect, the downscaling is performed using a method which represents a set of points based on a neighborhood or based on a previous set of data related to the location.

In a related aspect, the system further includes: when a database is available and a neural network which is pre-trained is available for requested data, using the neural network to perform the upscaling or the downscaling; and when the neural network is not available, the upscaling being performed using bicubic resampling or average pooling, and the downscaling being performed using a method based on interpolation that uses one data sample.

In another aspect according to the present invention, a computer program product to improve performance of a computer simulation using sampling includes the computer program product comprising a computer readable storage medium having program instructions embodied therewith. The program instructions are executable by a computer to cause the computer to perform functions, by the computer, comprising the functions to: process, using a computer, a resolution reduction of input data by an upscaling technique providing upscaling of the input data. The input data including a size and a resolution, a location, a date, conditioning points, and weather variable data, and the upscaling of the input data generating reduced resolution data having a reduced resolution and a reduced data size which is less resolution and less data size than the input data. The computer program product includes applying a multiple-point geostatistics technique to the reduced resolution data for generating, using the computer, a simulation of a new weather scenario, without changes in the reduced data size or the reduced +resolution to the reduced resolution data. The computer program product includes processing, using the computer, a resolution increase of the reduced resolution data from the simulation using a downscaling technique to return the reduced resolution data to the size and the resolution of the input data.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. The drawings are discussed forthwith below.

FIG. 1 is a flow chart of a process, according to an embodiment of the present disclosure, for generating digital simulations of weather scenarios using a sampling technique.

FIG. 2 is a schematic block diagram illustrating a system according to an embodiment of the present disclosure, for generating digital simulation of weather scenarios using a sampling technique.

FIG. 3 is a schematic block diagram illustrating a system according to an embodiment of the present disclosure, of a system to prepare a neural network.

FIG. 4 is a schematic block diagram illustrating a system according to an embodiment of the present disclosure, for generating digital simulations of weather scenarios using a sampling technique.

FIG. 5 is a flow chart of a method, according to an embodiment of the present disclosure, which can use the system depicted in FIG. 4, for generating digital simulations of weather scenarios using a sampling technique.

FIG. 6 is a schematic block diagram depicting a computer system according to an embodiment of the disclosure, which includes cloud computing components and functions, and which can cooperate with the systems and methods shown in the figures and described herein.

### DETAILED DESCRIPTION

In one embodiment according to the present disclosure, a method for improving performance of a computer simulation using sampling includes processing includes, using a computer, a resolution reduction of input data by an upscaling technique providing upscaling of the input data. The input data including a size and a resolution, a location, a date, conditioning points, and weather variable data. The upscaling of the input data generating reduced resolution data having a reduced resolution and a reduced data size which is less resolution and less data size than the input data. The method includes applying a multiple-point geostatistics technique to the reduced resolution data for generating, using the computer, a simulation of a new weather scenario, without changes in the reduced data size or the reduced resolution of the reduced resolution data. The method includes processing, using the computer, a resolution increase of the reduced resolution data from the simulation using a downscaling technique to return the reduced resolution data to the size and the resolution of the input data. Thereby, improving performance of a computer simulation using sampling.

In a related feature, the simulation is a digital weather simulation based on the reduced resolution data. Thereby, the method uses the reduced resolution data as detailed in the method.

In a related feature, the input data includes information related to weather including location information including latitude and longitude, conditioning points, and weather information including weather conditions and a date. Thereby, the input data is further defined.

In a related feature, the weather variables and conditions are received from a computer of a user and related to a specific location. Thereby, the data is further described and in one example received from a computer of a user.

In a related feature, the generated simulation is the same size as the size of the input data when received at the computer. Thereby, further defining the generated simulation.

In a related feature, the multipoint geostatistics technique is a direct sampling method, or a parallel direct sampling method. Thereby, presenting examples of the multipoint geostatistics technique.

In a related feature, the upscaling is performed using a method which represents one point based on a set of points. Thereby, presenting an example for performing the upscaling.

In a related feature, the downscaling is performed using a method which represents a set of points based on a neighborhood or based on a previous set of data related to the location. Thereby, presenting an example for performing the downscaling.

In a related feature, the method further includes: when there is a database and a neural network which is pre-trained available for requested data, using the neural network to perform the upscaling or the downscaling; and when the neural network is not available, the upscaling being performed using bicubic resampling or average pooling, and the downscaling being performed using a method based on interpolation that uses one data sample. Thereby, presenting alternative techniques for the upscaling and the downscaling.

In a related feature, the method further including: performing upsampling and downsampling using one or more methods excluding a generative neural network when the neural network is unavailable; and performing upsampling and downsampling using the generative neural network, when the neural network is available with training data. Thereby, presenting alternative techniques for the upsampling and the downsampling.

In another embodiment according to the present disclosure, a system to improve performance of a computer simulation using sampling includes a computer system. The computer system comprises; a computer processor, a computer-readable storage medium, and program instructions stored on the computer-readable storage medium being executable by the processor, to cause the computer system to perform the following functions. Process, using a computer, a resolution reduction of input data by an upscaling technique providing upscaling of the input data, the input data including a size and a resolution, a location, a date, conditioning points, and weather variable data. The upscaling of the input data generating reduced resolution data having a reduced resolution and a reduced data size which is less resolution and less data size than the input data. Apply a multiple-point geostatistics technique to the reduced resolution data to generate, using the computer, a simulation of a new weather scenario, without changes in the reduced data size or the reduced resolution to the reduced resolution data. Process, using the computer, a resolution increase of the reduced resolution data from the simulation using a downscaling technique to return the reduced resolution data to the size and the resolution of the input data. Thereby, improving performance of a computer simulation using sampling.

In a related feature, the simulation is a digital weather simulation based on the reduced resolution data. Thereby, the system uses the reduced resolution data as detailed.

In a related feature, the input data is information related to weather including location information including latitude and longitude, conditioning points, and weather information including weather conditions and a date. Thereby, the input data is further defined.

In a related feature, the weather variables and the conditions are received from a computer of a user and related to a specific location. Thereby, the input data is further described and received from a computer of a user.

In a related feature, the generated simulation is the same size as the size of the input data when received at the computer. Thereby, further defining the generated simulation.

In a related feature, the multipoint geostatistics technique is a direct sampling method, or a parallel direct sampling method. Thereby, presenting examples of the multipoint geostatistics technique.

In a related feature, the upscaling is performed using a method which represents one point based on a set of points. Thereby, further defining an example of the upscaling.

In a related aspect, the downscaling is performed using a method which represents a set of points based on a neighborhood or based on a previous set of data related to the location. Thereby, presenting an example of the downscaling.

In a related aspect, the system further includes: when a database is available and a neural network which is pre-trained is available for requested data, using the neural network to perform the upscaling or the downscaling; and when the neural network is not available, the upscaling being performed using bicubic resampling or average pooling, and the downscaling being performed using a method based on interpolation that uses one data sample. Thereby, presenting examples of using a neural network or alternatives for the upscaling and the downscaling.

In another embodiment according to the present disclosure, a computer program product to improve performance of a computer simulation using sampling includes the computer program product comprising a computer readable storage medium having program instructions embodied therewith. The program instructions are executable by a computer to cause the computer to perform functions, by the computer, comprising the functions to: process, using a computer, a resolution reduction of input data by an upscaling technique providing upscaling of the input data. The input data including a size and a resolution, a location, a date, conditioning points, and weather variable data, and the upscaling of the input data generating reduced resolution data having a reduced resolution and a reduced data size which is less resolution and less data size than the input data. The computer program product includes applying a multiple-point geostatistics technique to the reduced resolution data for generating, using the computer, a simulation of a new weather scenario, without changes in the reduced data size or the reduced resolution to the reduced resolution data. The computer program product includes processing, using the computer, a resolution increase of the reduced resolution data from the simulation using a downscaling technique to return the reduced resolution data to the size and the resolution of the input data. Thereby, improving performance of a computer simulation using sampling.

### EMBODIMENTS AND EXAMPLES

The following description with reference to the accompanying drawings is provided to assist in a comprehensive understanding of exemplary embodiments of the invention as defined by the claims and their equivalents. The description includes various specific details to assist in that understanding, but these are to be regarded as merely exemplary, and assist in providing clarity and conciseness. Accordingly, those of ordinary skill in the art will recognize that various changes and modifications of the embodiments described herein can be made without departing from the scope and spirit of the invention. In addition, descriptions of well-known functions and constructions may be omitted.

The terms and words used in the following description and claims are not limited to the bibliographical meanings, but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Embodiments and figures of the present disclosure may have the same or similar components as other embodiments. Such figures and descriptions illustrate and explain further examples and embodiments according to the present disclosure. Embodiments of the present disclosure can include operational actions and/or procedures. A method, such as a computer-implemented method, can include a series of operational blocks for implementing an embodiment according to the present disclosure which can include cooperation with one or more systems shown in the figures. The operational blocks of the methods and systems according to the present disclosure can include techniques, mechanism, modules, and the like for implementing the functions of the operations in accordance with the present disclosure. Similar components may have the same reference numerals. Components can operate in concert with a computer implemented method. It is understood that a customer can be an individual, or a group of individuals, or a company or an organization.

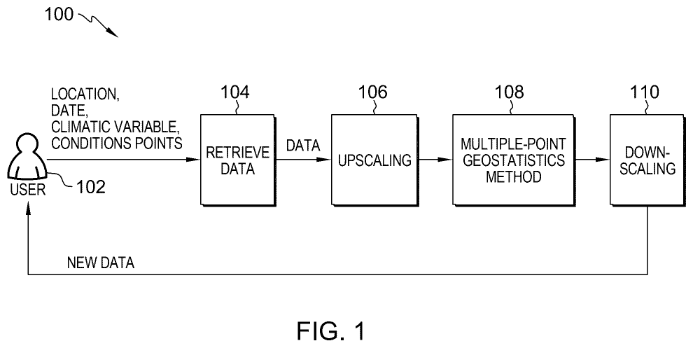

According to an embodiment of the present disclosure, a method 100 can improve the performance of a direct sampling algorithm, as shown in FIG. 1, for generating weather scenarios in computational time by providing a system of reducing scale. The method 100 can retrieve data, at operation 104, from a user 102, for example, a user using a computer. The data can include location data, climatic variables, or conditions points. The method 100 optimizes the use of a weather scenario generation by reducing the input data size using an upscaling technique, at operation 106, and applying direct sampling as one embodiment of a multiple-point geostatistics method, as in operation 108, and producing new scenarios, then perform downscaling, as in operation 110, using a proper method to return to the initial size, that is, the input data size. The new data resulting from downscaling can be transmitted to the user 102 as shown in FIG. 1. The new data is a new scenario which can be related to the same latitude and longitude of the input data and the same resolution as the input data. The new data is a result of the downscaling (which increases resolution) as the input data was subjected to upscaling (which decreased resolution), thus the new data has the same resolution as the input data.

More specifically regarding conditioning points, conditioning points can be used to change a scenario by setting a climate variable value for a specific location. For example, a conditioning point A can be represented as [Mar. 2, 2018, [−45,112], 40 mm], which indicates on the date of Mar. 2, 2018, at location [−45,112] the precipitation should be 40 mm. Such conditions can be informed to a system to generate a new scenario, wherein the user can inform or input the data which can include climate variables, a data and a location.

More specifically regarding climatic variables, climatic variables can include precipitation data, wind data, humidity data, temperature data, etc.

In one example, scale is related to resolution such that how many physical metric, for example in meters, fit inside a pixel. For example, a satellite image sentinel can have 30 m of resolution, so one pixel represents 30 meters. The size means how many pixels the image has, for example, 256 pixels by 256 pixels. In another example, a user can insert input data, for example, 256 pixels by 256 pixels and get from the system a new scenario with 256 pixels by 256 pixels.

Further clarifying, it is understood that upsampling equates to downscaling which results in increasing the resolution of the data. Upscaling equates to downsampling which results in reducing the resolution of the data.

It is further understood that upsampling and downsampling can be a simple or complex method wherein simple methods can include average pooling (e.g., computing the average of some window [3×3], in order to get worse resolution), or interpolation (e.g., extrapolating some additional points between two points in order to increase resolution). A complex methods can include a neural network model of superesolution that has many samples from the same location, in the past, in low and high resolution to be trained.

Thereby, the method of the present disclosure avoids using large data and large data processing, by scaling up and down for a computer simulation, thereby saving computational bandwidth, data space, and processing resources.

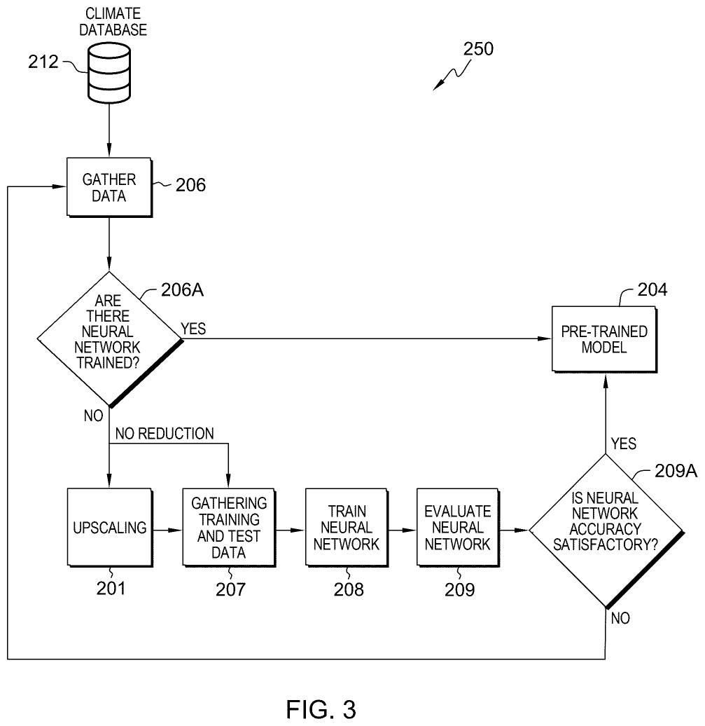

In one embedment, a system according to the present disclosure can offer to the user the upscaling/downscaling method available and can ask for a desired location to create a new weather scenario. The system identifies if there is a database and a neural network for the requested data, if it exists, the neural network is used to perform the downscaling, or if it does not exist, a downscaling is performed using a method that needs only one data sample as input data, as shown in FIG. 3.

In one embodiment according to the present disclosure, a system or a method to generate computerized weather scenarios using an optimal multiple-point geostatistics method. The system or method to generate weather scenarios using an optimal multiple-point geostatistics method provides a client API (Application Programming Interface) that returns new weather scenarios according to location, date, weather variables and conditions informed by the user to the system or method, for example using a control computer. The system or method can perform an upsampling and downsampling allowing a quick direct sampling running. The system and method provides a system to perform the downsampling using generative neural networks. The system or method provides a system that can replace the direct sampling method for a parallel method if there are available cores. The system and method offers the possibility to perform upsampling and downsampling using methods such as average pooling and interpolation, or a more complex method using generative neural networks which need training data.

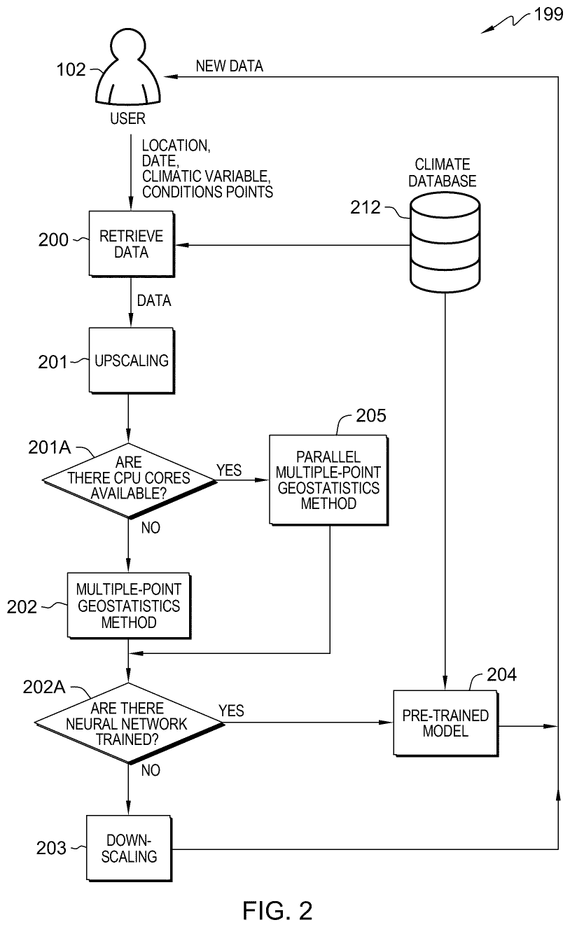

Referring to FIG. 2, according to an embodiment of the present disclosure, a system 199 generates weather scenarios using optimal multiple-point geostatistics. In the system 199, the user 102 can supply, using a user computer or device, data which can include a location, a date, a climatic variable, and condition points, which is retrieved using a computer of the system 199 by a retrieve data function 200. The retrieve data function 200 can also collect data from a climate database 212 that has climatic variables, a location, and a date, which in one embodiment can be supplied by the user. The climate variable can be a precipitation measurement, a temperature measurement, a pressure measurement, and other variables. The climate variable can include a date and a location, latitude and longitude coordinates, which can be supplied by the user using a computer or device. The user can also provide conditioning points that can be maintained from the original image for a simulation.

The system 199 receives the data at the upscaling function 201 that will be simulated, and processes the data reduction by upscaling, which generates smaller data to apply a direct sampling method or a parallel direct sampling method, or any other multiple-point geostatistics method. Various techniques may be employed to determine the upscaling. Bicubic resampling or average pooling can be used, for example, as an upscaling technique.

At operation 201A, the system determines if CPU (Central Processing Unit) is available. If the CPU is available, the system proceeds to a parallel multiple-point geostatistics method, as in function 205. If the CPU is not available, the system proceeds to function 202.

The reduced data processed by upscaling is received at the function 202 and the function 202 processes the upscaled data reduction using a multiple-point geostatistics method to generate a simulation of the same size as the received data, using, for example, a direct sampling method or any other multiple-point geostatistics method.

At operation 202A, the system determines if a neural network is trained. If a neural network is trained, the system proceeds to a pre-trained model at function 204. If a neural network is not trained, the system proceeds to function 203.

The function 203 receives the simulation generated by, for example, the direct sampling method or a parallel direct sampling method, or any other multiple-point geostatistics method, and processes the scale increase by a downscaling method, generating the data on the same scale as initially received.

The function 204 receives the simulation performed by a direct sampling method, or a parallel direct sampling method, or any other multiple-point geostatistics method, and processes the scale increase by a neural network using a pre-trained model, to generate the data on the same scale as initially received. A super resolution generative adversarial network can be used as a neural network.

Function 205 receives the reduced data and processes the reduced data using the parallel direct sampling method, or any other multiple-point geostatistics method, to generate a simulation of the same size as the received data. Bicubic interpolation can be used as a downscaling technique.

Referring to FIG. 3, in another embodiment according to the present disclosure, a system 250 depicts an offline system to prepare a neural network. The system 250 depicts the offline system and method to generate a pre-trained model to use in the system 199. Function 206 collects relevant data for a given climate variable in order to prepare the training and test data. Operation 206A determines if the neural network is trained. The data includes a single variable that has a certain size. Function 207 receives the reduced data and the original data to prepare the training data and test data. The combination of reduced data and increased data is used to compose the training and test dataset. Function 208 receives the training data to perform a fine tuning of a neural network model. Function 209 receives the test data to evaluate the neural network model. The system 250 determines when the neural network has achieved a satisfactory accuracy at operation 209A. Various techniques may be employed to determine the accuracy as root mean square error and absolute error. When the accuracy is satisfactory, the system proceeds to function 204 having completed the pre-trained model.

### OTHER EXAMPLES AND EMBODIMENTS

In another embodiment according to the present disclosure, a comparison can made between a method of the present disclosure and a Direct Sampling method. The present invention can use precipitation data of 256×256 pixels as a training image and in one example according to the present disclosure can generate a simulation for this data. In one example, a sample is representing a specific location from a day of the year, the climatic variable is precipitation, and the method is using 3% of the image as a conditioning point (a point that the method should maintain).

A simulation can be generated using the Direct Sampling method. In this case with an input image size of 256×256 pixels, it takes a computational time of 35,554 seconds, approximately 10 hours, to generate the simulation.

Using the system including a super resolution network, according to the present disclosure, a simulation can be generated, when the system has a training data for a neural network to create a super resolution sample. An upscaling technique using the average pooling technique can be used, and a downscaling technique using a neural network SRGAN (a combination of generative adversarial networks (GANs) and deep convolutional neural networks (CNNs)) can be used, that was trained with a dataset using an offline system. In this scenario, with an input image size of 256×256 pixels, a computational time of 145 seconds, approximately 2 minutes, which is a speed gain compared to the example above using the direct sampling method of approximately 245 time.

The system can generate the simulation using the above technique when the system has no training data for that location. A method based on bicubic interpolation technique can be used for upscaling and downscaling. In this case a computational time of 141 seconds, approximately 2 minutes, the speed gain compared to the direct sampling method is 252 times. However, the method without the neural network loses in quality where high frequencies are neglected. In all examples a parallel method can improve the computational time, wherein the computational time can decrease 980 times.

### ADDITIONAL EXAMPLES AND EMBODIMENTS

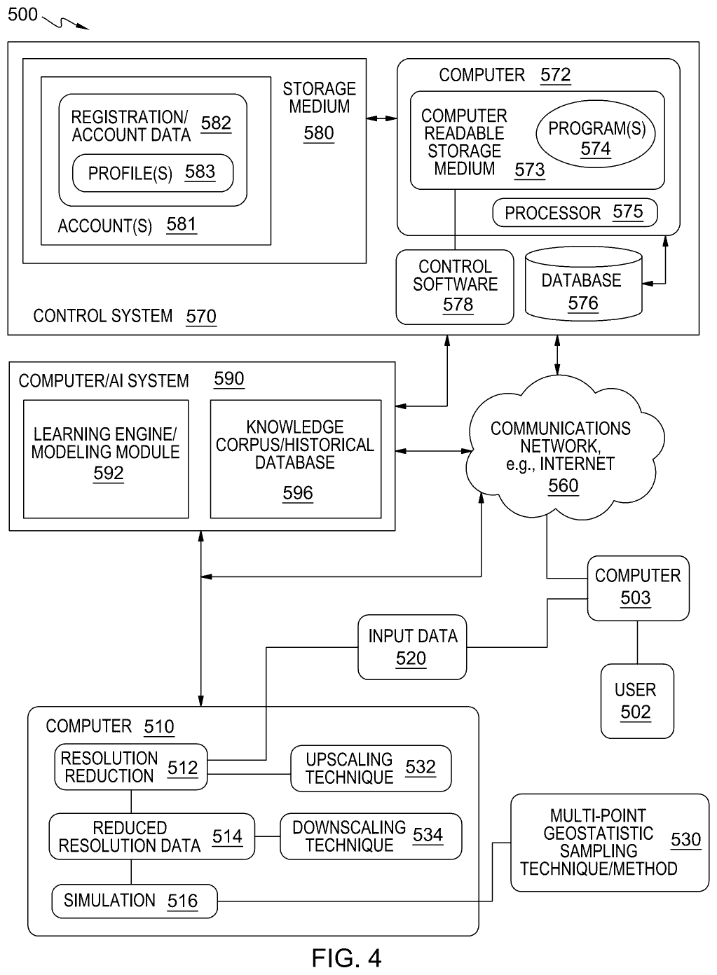

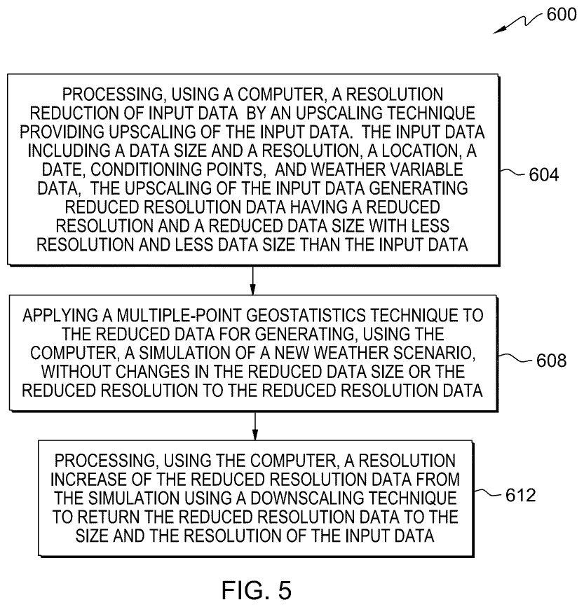

Referring to FIGS. 4 and 5, in one embodiment according to the present disclosure, a method 600 for improving performance of a computer simulation using sampling and can use a system 500. The method 600 includes processing, using a computer 510, a resolution reduction 512 of input data 520 at the computer by an upscaling technique 532 providing upscaling of the input data, as in operation 604. In one example, the input data received at the computer can includes variables. In another example, the input data includes information related to weather including weather variables and weather conditions. In another example, the input data includes a size and resolution, a location, a date, conditioning points and weather variable data. In another example, the weather variables and conditions are received from a computer 503 of a user 502 regarding the location.

The upscaling of the input data generates reduced resolution data 514 having a reduced resolution and a reduced data size which is less resolution and less data size than the input data, as in operation 604.

The input data has an input data size and the upscaling of the input data generates resolution reduction of the input data having a reduced resolution and reduced data size where the reduced data size is less than the input data size.

The method 600 includes applying a multiple-point geostatistics technique 530 to the reduced resolution data for generating, using the computer, a simulation 516 of a new weather scenario without changes in the reduced data size or the reduced resolution to the reduced resolution data 520, as in operation 608. In one example, the simulation can be a digital weather simulation based on the reduced resolution data.

The method 600 includes processing, using the computer, a resolution increase of the reduced resolution data in the simulation using a downscaling technique 534 to return the reduced resolution data to the size and the resolution of the input data, as in operation 612.

In one example, the simulation is a digital weather simulation based on the reduced resolution data.

In another example, the input data includes information related to weather including location information including latitude and longitude, conditioning points, and weather information including a weather condition and a date.

In another example, the weather variables and weather conditions are received from a computer 503 of a user 502 and related to a specific location.

In one example, the generated simulation of the new weather scenario is the same data size as the reduced data size.

In another example, the multipoint geostatistics technique is a direct sampling method, or a parallel direct sampling method. Alternatively, the sampling technique can be any other sampling technique that uses a multipoint geostatistics technique 530 to generate data with variability.

In another example, the upscaling can be performed using a method which represents one point based on a set of points. For example, method for upscaling can include bicubic resampling, average pooling, or another method which can represent one point based on a set of points.

In another example, downscaling (using a downscaling technique 534) can be performed using a method which represents a set of points based on a neighborhood or based on a previous set of data related to the location or the same location as the input data.

In another example, the method can further include, when there is a database available and a neural network available which is pre-trained for requested data, using the neural network (as one example of a downscaling technique 534) to perform the downscaling. And when the neural network is not available, the upscaling can be performed using upscaling techniques 532 such as bicubic resampling or average pooling, and the downscaling can be performed using a method based on interpolation that uses one data sample.

In another example, the method can further include performing upsampling and downsampling using one or more methods excluding generative neural networks when one or more neural networks are unavailable. The performing of the upsampling and downsampling can use generative neural networks, when the one or more neural networks are available with training data.

In another embodiment according to an invention a system to improve performance of a computer simulation using sampling includes a computer system. The computer system includes a computer processor, a computer-readable storage medium, and program instructions stored on the computer-readable storage medium being executable by the processor, to cause the computer system to perform the following functions. A function to process, using a computer, a resolution reduction of input data by an upscaling technique providing upscaling of the input data, the input data including a size and a resolution, a location, a date, conditioning points, and weather variable data, and the upscaling of the input data generating reduced resolution data having a reduced resolution and a reduced data size which is less resolution and less data size than the input data. A function to apply a multiple-point geostatistics technique to the reduced data to generate, using the computer, a simulation of a new weather scenario, without changes in the reduced data size or the reduced resolution to the reduced resolution data. A function to process, using the computer, a resolution increase of the reduced resolution data from the simulation using a downscaling technique to return the reduced resolution data to the size and the resolution of the input data.

In another embodiment according to the present disclosure, a computer program product to improve performance of a computer simulation uses sampling. The computer program product includes a computer readable storage medium having program instructions embodied therewith, the program instructions executable by a computer to cause the computer to perform functions, by the computer, including the following functions. A function to process, using a computer, a resolution reduction of input data by an upscaling technique providing upscaling of the input data. The input data including a size and a resolution, a location, a date, and conditioning points, and the weather variable data, and the upscaling of the input data generating reduced resolution data having a reduced resolution and a reduced data size which is less resolution and less data size than the input data. A function to apply a multiple-point geostatistics technique to the reduced resolution data for generating, using the computer, a simulation of a new weather scenario, without changes in the reduced data size or the reduced resolution to the reduced resolution data. A function to process, using the computer, a resolution increase of the reduced resolution data from the simulation using a downscaling technique to return the reduced resolution data to the size and the resolution of the input data.

### ADDITIONAL EMBODIMENTS AND EXAMPLES

Again referring to FIG. 4, a system 500 includes a computer 572 which can be integral to or communicating with a device, and communicate with other computers such as computer 510. A computer 590 remote from the computer 510 can electronically communicate, in all or in part, with a control system computer 572 as part of a control system 570. The control system 570 can include the computer 572 having a computer readable storage medium 573 which can store one or more programs 574, and a processor 575 for executing program instructions. The control system 570 can include control software 578 for managing the one or more programs. The control system can also include a storage medium which can include registration and/or account data 582 and user profiles 583 of users or entities (such entities can include robotic entities) as part of user accounts 581. User accounts 581 can be stored on a storage medium 580 which is part of the control system 570. The user accounts 581 can include registrations and account data 582 and user profiles 583. The control system can also include the computer 572 having a computer readable storage medium 573 which can store programs or code embedded on the storage medium. The program code can be executed by a processor 575. The computer 572 can communicate with a database 576. The control system 570 can also include a database 576 for storing all or part of such data as described above, and other data.

The control system 570 can also communicate with the computer 510 which can include a learning engine/module 592 and a knowledge corpus or database 596. The computer system 590 can also communicate with the computer 510 and can be remote from a user 502 and a computer 510. The depiction of the computer 510 as well as the other components of the system 500 are shown as one example according to the present disclosure. One or more computer systems can communicate with a communications network 560, e.g., the Internet.

### STILL FURTHER EMBODIMENTS AND EXAMPLES

Account data, for instance, including profile data related to a user, and any data, personal or otherwise, can be collected and stored, for example, in a control system. It is understood that such data collection is done with the knowledge and consent of a user, and stored to preserve privacy, which is discussed in more detail below. Such data can include personal data, and data regarding personal items. Regarding collection of data with respect to the present disclosure, such uploading or generation of profiles is voluntary by the one or more users, and thus initiated by and with the approval of a user. Thereby, a user can opt-in to establishing an account having a profile according to the present disclosure. Thereby, a user can opt-in to input data according to the present disclosure. Such user approval also includes a user's option to cancel such profile or account, and/or input of data, and thus opt-out, at the user's discretion, of capturing communications and data. Further, any data stored or collected is understood to be intended to be securely stored and unavailable without authorization by the user, and not available to the public and/or unauthorized users. Such stored data is understood to be deleted at the request of the user and deleted in a secure manner. Also, any use of such stored data is understood to be, according to the present disclosure, only with the user's authorization and consent.

### MORE EXAMPLES AND EMBODIMENTS

Additionally, methods and systems according to embodiments of the present disclosure can be discussed in relation to a functional system(s) depicted by functional block diagrams. The methods and systems can include components and operations for embodiments according to the present disclosure and is used herein for reference when describing the operational steps of the methods and systems of the present disclosure. Additionally, the functional system, according to an embodiment of the present disclosure, depicts functional operations indicative of the embodiments discussed herein.

The methods and systems of the present disclosure can include a series of operational blocks for implementing one or more embodiments according to the present disclosure. A method shown in the figures may be another example embodiment, which can include aspects/operations shown in another figure and discussed previously but can be reintroduced in another example. Thus, operational blocks and system components shown in one or more of the figures may be similar to operational blocks and system components in other figures. The diversity of operational blocks and system components depict example embodiments and aspects according to the present disclosure. For example, methods shown are intended as example embodiments which can include aspects/operations shown and discussed previously in the present disclosure, and in one example, continuing from a previous method shown in another flow chart.

It is understood that the features shown in some of the figures, for example block diagrams, are functional representations of features of the present disclosure. Such features are shown in embodiments of the systems and methods of the present disclosure for illustrative purposes to clarify the functionality of features of the present disclosure.

### FURTHER DISCUSSION REGARDING EXAMPLES AND EMBODIMENTS

It is understood that a set or group is a collection of distinct objects or elements. The objects or elements that make up a set or group can be anything, for example, numbers, letters of the alphabet, other sets, a number of people or users, and so on. It is further understood that a set or group can be one element, for example, one thing or a number, in other words, a set of one element, for example, one or more users or people or participants. It is also understood that machine and device are used interchangeable herein to refer to machine or devices in one or ecosystems or environments, which can include, for example and artificial intelligence (AI) environment.

The descriptions of the various embodiments of the present invention have been presented for purposes of illustration but are not intended to be exhaustive or limited to the embodiments disclosed. Likewise, examples of features or functionality of the embodiments of the disclosure described herein, whether used in the description of a particular embodiment, or listed as examples, are not intended to limit the embodiments of the disclosure described herein, or limit the disclosure to the examples described herein. Such examples are intended to be examples or exemplary, and non-exhaustive. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

It is also understood that the one or more computers or computer systems shown in the figures can include all or part of a computing environment and its components shown in another figure, for example, the computing environment 1000 can be incorporated, in all or in part, in one or more computers or devices shown in other figures and described herein. In one example, the one or more computers can communicate with all or part of a computing environment and its components as a remote computer system to achieve computer functions described in the present disclosure.

### MORE ADDITIONAL EXAMPLES AND EMBODIMENTS

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

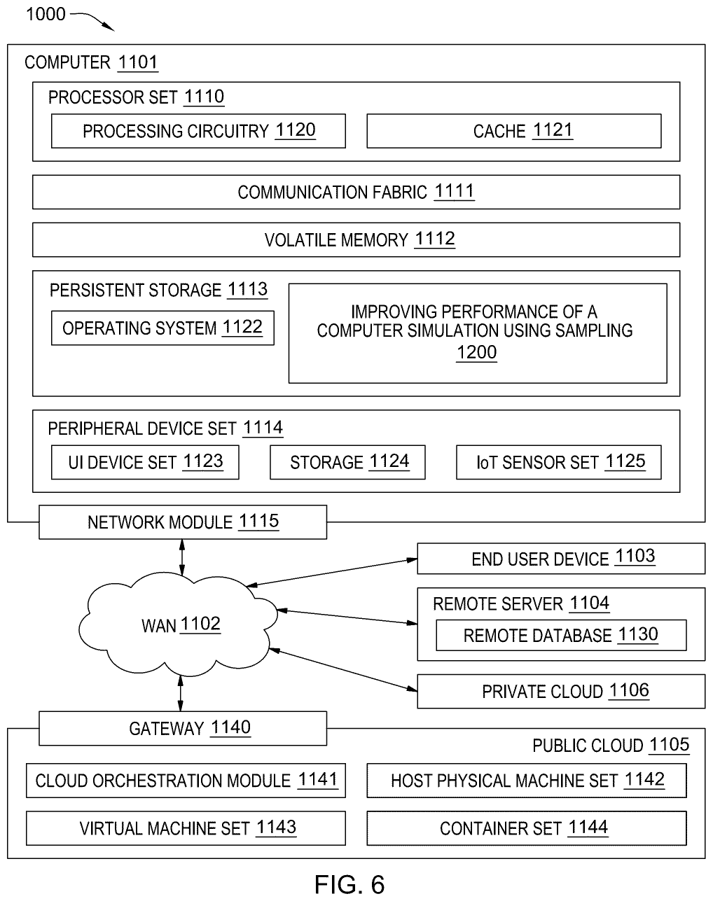

Referring to FIG. 6, a computing environment 1000 contains an example of an environment for the execution of at least some of the computer code involved in performing the inventive methods, such as improving performance of a computer simulation using sampling 1200. In addition to block 1200, computing environment 1000 includes, for example, computer 1101, wide area network (WAN) 1102, end user device (EUD) 1103, remote server 1104, public cloud 1105, and private cloud 1106. In this embodiment, computer 1101 includes processor set 1110 (including processing circuitry 1120 and cache 1121), communication fabric 1111, volatile memory 1112, persistent storage 1113 (including operating system 1122 and block 1200, as identified above), peripheral device set 1114 (including user interface (UI), device set 1123, storage 1124, and Internet of Things (IoT) sensor set 1125), and network module 1115. Remote server 1104 includes remote database 1130. Public cloud 1105 includes gateway 1140, cloud orchestration module 1141, host physical machine set 1142, virtual machine set 1143, and container set 1144.

COMPUTER 1101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1130. As is well understood in the art of computer technology, and depending upon the technology, performance of a computer-implemented method may be distributed among multiple computers and/or between multiple locations. On the other hand, in this presentation of computing environment 1100, detailed discussion is focused on a single computer, specifically computer 1101, to keep the presentation as simple as possible. Computer 1101 may be located in a cloud, even though it is not shown in a cloud in FIG. 7. On the other hand, computer 1101 is not required to be in a cloud except to any extent as may be affirmatively indicated.

PROCESSOR SET 1110 includes one, or more, computer processors of any type now known or to be developed in the future. Processing circuitry 1120 may be distributed over multiple packages, for example, multiple, coordinated integrated circuit chips. Processing circuitry 1120 may implement multiple processor threads and/or multiple processor cores. Cache 1121 is memory that is located in the processor chip package(s) and is typically used for data or code that should be available for rapid access by the threads or cores running on processor set 1110. Cache memories are typically organized into multiple levels depending upon relative proximity to the processing circuitry. Alternatively, some, or all, of the cache for the processor set may be located “off chip.” In some computing environments, processor set 1110 may be designed for working with qubits and performing quantum computing.

Computer readable program instructions are typically loaded onto computer 1101 to cause a series of operational steps to be performed by processor set 1110 of computer 1101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1121 and the other storage media discussed below. The program instructions, and associated data, are accessed by processor set 1110 to control and direct performance of the inventive methods. In computing environment 1100, at least some of the instructions for performing the inventive methods may be stored in block 1200 in persistent storage 1113.

COMMUNICATION FABRIC 1111 is the signal conduction paths that allow the various components of computer 1101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 1112 is any type of volatile memory now known or to be developed in the future. Examples include dynamic type random access memory (RAM) or static type RAM. Typically, the volatile memory is characterized by random access, but this is not required unless affirmatively indicated. In computer 1101, the volatile memory 1112 is located in a single package and is internal to computer 1101, but, alternatively or additionally, the volatile memory may be distributed over multiple packages and/or located externally with respect to computer 1101.

PERSISTENT STORAGE 1113 is any form of non-volatile storage for computers that is now known or to be developed in the future. The non-volatility of this storage means that the stored data is maintained regardless of whether power is being supplied to computer 1101 and/or directly to persistent storage 1113. Persistent storage 1113 may be a read only memory (ROM), but typically at least a portion of the persistent storage allows writing of data, deletion of data and re-writing of data. Some familiar forms of persistent storage include magnetic disks and solid state storage devices. Operating system 1122 may take several forms, such as various known proprietary operating systems or open source Portable Operating System Interface type operating systems that employ a kernel. The code included in block 1200 typically includes at least some of the computer code involved in performing the inventive methods.

PERIPHERAL DEVICE SET 1114 includes the set of peripheral devices of computer 1101. Data communication connections between the peripheral devices and the other components of computer 1101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1123 may include components such as a display screen, speaker, microphone, wearable devices (such as goggles and smart watches), keyboard, mouse, printer, touchpad, game controllers, and haptic devices. Storage 1124 is external storage, such as an external hard drive, or insertable storage, such as an SD card. Storage 1124 may be persistent and/or volatile. In some embodiments, storage 1124 may take the form of a quantum computing storage device for storing data in the form of qubits. In embodiments where computer 1101 is required to have a large amount of storage (for example, where computer 1101 locally stores and manages a large database) then this storage may be provided by peripheral storage devices designed for storing very large amounts of data, such as a storage area network (SAN) that is shared by multiple, geographically distributed computers. IoT sensor set 1125 is made up of sensors that can be used in Internet of Things applications. For example, one sensor may be a thermometer and another sensor may be a motion detector.

NETWORK MODULE 1115 is the collection of computer software, hardware, and firmware that allows computer 1101 to communicate with other computers through WAN 1102. Network module 1115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1115 are performed on the same physical hardware device. In other embodiments (for example, embodiments that utilize software-defined networking (SDN)), the control functions and the forwarding functions of network module 1115 are performed on physically separate devices, such that the control functions manage several different network hardware devices. Computer readable program instructions for performing the inventive methods can typically be downloaded to computer 1101 from an external computer or external storage device through a network adapter card or network interface included in network module 1115.

WAN 1102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 1103 is any computer system that is used and controlled by an end user (for example, a customer of an enterprise that operates computer 1101) and may take any of the forms discussed above in connection with computer 1101. EUD 1103 typically receives helpful and useful data from the operations of computer 1101. For example, in a hypothetical case where computer 1101 is designed to provide a recommendation to an end user, this recommendation would typically be communicated from network module 1115 of computer 1101 through WAN 1102 to EUD 1103. In this way, EUD 1103 can display, or otherwise present, the recommendation to an end user. In some embodiments, EUD 1103 may be a client device, such as thin client, heavy client, mainframe computer, desktop computer and so on.

REMOTE SERVER 1104 is any computer system that serves at least some data and/or functionality to computer 1101. Remote server 1104 may be controlled and used by the same entity that operates computer 1101. Remote server 1104 represents the machine(s) that collect and store helpful and useful data for use by other computers, such as computer 1101. For example, in a hypothetical case where computer 1101 is designed and programmed to provide a recommendation based on historical data, then this historical data may be provided to computer 1101 from remote database 1130 of remote server 1104.

PUBLIC CLOUD 1105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1105 is performed by the computer hardware and/or software of cloud orchestration module 1141. The computing resources provided by public cloud 1105 are typically implemented by virtual computing environments that run on various computers making up the computers of host physical machine set 1142, which is the universe of physical computers in and/or available to public cloud 1105. The virtual computing environments (VCEs) typically take the form of virtual machines from virtual machine set 1143 and/or containers from container set 1144. It is understood that these VCEs may be stored as images and may be transferred among and between the various physical machine hosts, either as images or after instantiation of the VCE. Cloud orchestration module 1141 manages the transfer and storage of images, deploys new instantiations of VCEs and manages active instantiations of VCE deployments. Gateway 1140 is the collection of computer software, hardware, and firmware that allows public cloud 1105 to communicate through WAN 1102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 1106 is similar to public cloud 1105, except that the computing resources are only available for use by a single enterprise. While private cloud 1106 is depicted as being in communication with WAN 1102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1105 and private cloud 1106 are both part of a larger hybrid cloud.

What is claimed is:

1. A method for improving performance of a computer simulation using sampling, comprising:
processing, using a computer, a resolution reduction of input data by an upscaling technique providing upscaling of the input data, the input data including a data size and a resolution, a location, a date, conditioning points, and weather variable data, and the upscaling of the input data generating reduced resolution data having a reduced resolution and a reduced data size which is less resolution and less data size than the input data;
applying a multiple-point geostatistics technique to the reduced resolution data for generating, using the computer, a simulation of a new weather scenario, without changes in the reduced data size or the reduced resolution to the reduced resolution data; and
processing, using the computer, a resolution increase of the reduced resolution data from the simulation using a downscaling technique to return the reduced resolution data to the size and the resolution of the input data.

2. The method of claim 1, wherein the simulation is a digital weather simulation based on the reduced resolution data.

3. The method of claim 1, wherein the input data includes information related to weather including location information including latitude and longitude, conditioning points, and weather information including weather conditions and a date.

4. The method of claim 3, wherein the weather variables and conditions are received from a computer of a user and related to a specific location.

5. The method of claim 1, wherein the generated simulation is the same size as the size of the input data when received at the computer.

6. The method of claim 1, wherein the multipoint geostatistics technique is a direct sampling method, or a parallel direct sampling method.

7. The method of claim 1, wherein the upscaling is performed using a method which represents one point based on a set of points.

8. The method of claim 1, wherein the downscaling is performed using a method which represents a set of points based on a neighborhood or based on a previous set of data related to the location.

9. The method of claim 1, further comprising:
when there is a database available and a neural network which is pre-trained is available for requested data, using the neural network to perform the upscaling or the downscaling; and
when the neural network is not available, the upscaling being performed using bicubic resampling or average pooling, and the downscaling being performed using a method based on interpolation that uses one data sample.

10. The method of claim 1, further comprising:
performing upsampling and downsampling using one or more methods excluding a generative neural network when the neural network is unavailable; and
performing upsampling and downsampling using the generative neural network, when the neural network is available with training data.

11. A system to improve performance of a computer simulation using sampling, which comprises:
a computer system comprising; a computer processor, a computer-readable storage medium, and program instructions stored on the computer-readable storage medium being executable by the processor, to cause the computer system to perform the following functions to;
process, using a computer, a resolution reduction of input data by an upscaling technique providing upscaling of the input data, the input data including a size and a resolution, a location, a date, conditioning points, and weather variable data, and the upscaling of the input data generating reduced resolution data having a reduced resolution and a reduced data size which is less resolution and less data size than the input data;
apply a multiple-point geostatistics technique to the reduced resolution data to generate, using the computer, a simulation of a new weather scenario, without changes in the reduced data size or the reduced resolution to the reduced resolution data; and
process, using the computer, a resolution increase of the reduced resolution data from the simulation using a downscaling technique to return the reduced resolution data to the size and the resolution of the input data.

12. The system of claim 11, wherein the simulation is a digital weather simulation based on the reduced resolution data.

13. The system of claim 11, wherein the input data includes information related to weather including location information including latitude and longitude, conditioning points, and weather information including weather conditions and a date.

14. The system of claim 11, wherein the weather variables and the conditions are received from a computer of a user and related to a specific location.

15. The system of claim 11, wherein the generated simulation is the same size as the size of the input data when received at the computer.

16. The system of claim 11, wherein the multipoint geostatistics technique is a direct sampling method, or a parallel direct sampling method.

17. The system of claim 10, wherein the upscaling is performed using a method which represents one point based on a set of points.

18. The system of claim 10, wherein the downscaling is performed using a method which represents a set of points based on a neighborhood or based on a previous set of data related to the location.

19. The system of claim 10, further comprising:
when a database is available and a neural network which is pre-trained is available for requested data, using the neural network to perform the upscaling or the downscaling; and
when the neural network is not available, the upscaling being performed using bicubic resampling or average pooling, and the downscaling being performed using a method based on interpolation that uses one data sample.

20. A computer program product to improve performance of a computer simulation using sampling, the computer program product comprising a computer readable storage medium having program instructions embodied therewith, the program instructions executable by a computer to cause the computer to perform functions, by the computer, comprising the functions to:
process, using a computer, a resolution reduction of input data by an upscaling technique providing upscaling of the input data, the input data including a size and a resolution, a location, a date, conditioning points, and weather variable data, and the upscaling of the input data generating reduced resolution data having a reduced resolution and a reduced data size which is less resolution and less data size than the input data;
applying a multiple-point geostatistics technique to the reduced resolution data for generating, using the computer, a simulation of a new weather scenario, without changes in the reduced data size or the reduced resolution to the reduced resolution data; and
processing, using the computer, a resolution increase of the reduced resolution data from the simulation using a downscaling technique to return the reduced resolution data to the size and the resolution of the input data.
